(19) United States
(12) Patent Application Publication
(10) Pub. No.: US 2010/0129623 A1
(43) Pub. Date: May 27, 2010

(54) Active Sensor Surface and a Method for Manufacture Thereof

(75) Inventors: Anders Johansson, Uppsala (SE); Mårten Rooth, Uppsala (SE); Mats Boman, Jarlasa (SE); Anders Hårsta, Balinge (SE); Jan-Otto Carlsson, Uppsala (SE)

Correspondence Address: PORTER WRIGHT MORRIS & ARTHUR, LLP;INTELLECTUAL PROPERTY GROUP, 41 SOUTH HIGH STREET, 28TH FLOOR, COLUMBUS, OH, 43215, US

(73) Assignee: NANEXA AB

(21) Appl. No.: 12/523,347

(22) PCT Filed: Oct. 3, 2007
(86) PCT No.: PCT/SE2007/050702

§ 371 Date: Jan. 22, 2010

(30) Foreign Application Priority Data
Jan. 29, 2007 (SE) 0700225-6

(51) Int. Cl. B05D 1/36; C23C 14/34; C23F 1/00; B32B 5/16; B32B 3/10

(52) U.S. Cl. 428/206; 427/202; 204/192.15; 216/37; 428/323; 428/328; 977/734; 977/810; 977/893; 977/902; 977/891

(57) ABSTRACT

Briefly, the present invention comprises a method of manufacturing a sensor surface structure suitable for but not limited to surface enhanced Raman spectroscopy. The method comprises providing (S1) a nano-structured array template, depositing (S2) a metal oxide on the template, preferably using atomic layer deposition (ALD), depositing (S4) metal nanoparticles on the metal oxide layer, either by electroless deposition or by ALD.

### TECHNICAL FIELD

The present invention relates to nano-structured materials in general, specifically manufacturing nano structured surfaces suitable for Surface Enhanced Raman Spectroscopy.

### BACKGROUND

At present nanotechnology is an ever-expanding field of research. The interest lies in all areas of science, including mechanics, medicine, electronics, and active materials.

Specifically, the development of nano structured surfaces has become of large interest for areas such as catalysis and analysis. Materials of special interest are those offering opportunities of purposely designed surface enlargement down to the nano-scale. By using techniques for nano-structuring of surfaces, especially template-based techniques, controlled and enlarged surfaces can be obtained.

Known methods for obtaining tailored nano-structures include:
lithographic methods, where a surface is masked and further processed by using irradiation of different kinds. By using lithography it is difficult to obtain high aspect-ratio (depth over width) structures.
template based techniques, where a porous host material is used; other materials are deposited on/in the pore walls and the host material is subsequently removed by chemical etching.
self-assembly, where larger molecules are adsorbed to a surface and thereby affecting the surface chemical properties so that further deposition only occur at specific sites.

Known methods for obtaining nanoparticles on the pore walls of porous materials and on 3-D surfaces in general include:
synthesizing metal nanoparticles in a solution and attaching the particles on the pore walls using various chemical routes.
using metal containing clusters with a variety of stabilising ligands which are then attached to the pore walls and thermally treated to release nanoparticles on the pore walls.

One exemplary area of science that benefits from the use of nano structured materials is Raman spectroscopy, especially for selective detection of several molecules at the same time. Raman spectroscopy enables detection of fingerprint type of spectra, i.e., complicated spectra with several peaks, which are identified to certain molecules. Finger print types of spectra are normally located in the region 600-1200 cm⁻¹. Raman spectroscopy also distinguishes and detects different functional groups in a molecule, such as —NO2, —COOH, —CN, etc. Functional groups are found in the region 1200 to 3500 cm⁻¹. Until now a Raman spectrometer has been a complicated and very sensitive instrument. The reason for this is the need for a very high dispersion since most peaks in a Raman spectra are very close to the excitation wavelength 50-3000 cm⁻¹.

The main problem using a Raman spectrometer for detection of e.g. ultra low concentrations in the gas phase is the low sensitivity of the technique. In normal Raman spectroscopy only 1 out of 10⁷ photons are Raman scattered. Fortunately, the Raman signal can be amplified by the use of certain surfaces where surface enhanced Raman scattering occurs. The Raman scattering from a compound (or ion) adsorbed on or even within a few Angstroms of a structured metal surface can be 10³-10⁶× greater than in solution. This surface-enhanced Raman scattering is strongest on silver, but is observable on gold, copper, and palladium as well. At practical excitation wavelengths, enhancement on other metals is unimportant. Surface-enhanced Raman scattering (SERS) arises from two mechanisms.

The first is an enhanced electromagnetic field produced at the surface of the metal. When the wavelength of the incident light is close to the plasma wavelength of the metal, conduction electrons in the metal surface are excited into an extended surface electronic excited state called a surface plasmon resonance. Molecules adsorbed or in close proximity to the surface experience an exceptionally large electromagnetic field. Vibrational modes normal to the surface are most strongly enhanced.

The second mode of enhancement is by the formation of a charge-transfer complex between the surface and analyte molecule i.e. molecule to be analyzed or detected. The electronic transitions of many charge transfer complexes are in the visible, so that resonance enhancement occurs.

Molecules with lone-pair electrons or π-clouds show the strongest SERS. The effect was first discovered with pyridine. Other aromatic nitrogen or oxygen containing compounds, such as aromatic amines or phenols, are strongly SERS active. The effect can also be seen with other electron-rich functionalities such as carboxylic acids.

The intensity of the surface plasmon resonance is dependent on many factors including the wavelength of the incident light and the morphology of the metal surface. The wavelength should match the plasma wavelength of the metal. This is about 382 nm for a 5 nm silver particle, but can be as high as 600 nm for larger ellipsoidal silver particles. The plasma wavelength is to the red of 650 nm for copper and gold, the other two metals which show SERS at wavelengths in the 350-1000 nm region. The best morphology for surface plasmon resonance excitation is a small (<100 nm) particle or an atomically rough surface.

SERS is typically used to study mono-layers of materials adsorbed on metals, including electrodes. Many formats other than electrodes can be used. The most popular include colloids, metal films on dielectric substrates and, recently, arrays of metal particles bound to metal or dielectric colloids through short linkages.

Many studies have been performed for the purpose of creating e.g. a good SERS surface. Most of the studies have been based on lithographically patterned gold or silver surfaces, which give good control of the surface topography, but lack the highly enlarged surface, which is required for analysing very low concentrations.

Another addressed problem is the necessity of producing clean SERS surfaces. Since the detection limit for SERS is extremely low, only small amounts of contaminants will strongly affect the detection level.

Therefore, there is a need for improved nano structures with large surfaces, controllable particle size and distribution to provide highly sensitive sensors. Also it is necessary to be able to produce the SERS surface under controlled conditions to avoid contaminants.

### SUMMARY

An object of the present invention is to provide a method for nano-structure surfaces, enlarging the area substantially.

A further object is to provide a surface structure for improved Surface Enhanced Raman Spectroscopy (SERS).

Another object is to provide a method of manufacture of a SERS surface comprising free-standing metal oxide nanotubes or nanorods with nanoparticles attached to the walls.

Yet another object of the present invention is to provide a self-cleaning capable SERS surface structure.

These and other objects are achieved in accordance with the attached claims.

Briefly, the present invention comprises a method of manufacturing a structure suitable for but not limited to surface enhanced Raman spectroscopy.

Basically, the method comprises providing (S1) a nanostructured template, and depositing (S2) at least one layer of a metal oxide on the template. Subsequently, depositing (S4) nanoparticles in or on said deposited metal oxide layer.

According to a specific embodiment, the method comprises providing S1 a nanostructured template in the form of an anodic alumina membrane, and depositing S2 metal oxide on the pore walls of the pores of the membrane using atomic layer deposition (ALD). The alumina membrane is optionally removed S3 by chemical etching and freestanding nanotubes of the deposited metal oxide are obtained. The metal oxide nano-tubes are further subjected S4 to deposition of metal nanoparticles, either by electroless deposition or ALD.

According to another specific embodiment, the method comprises providing S1 a nanostructured template in the form of an array of nano-rods or whiskers, depositing S2 at least a layer of a metal oxide on the nano-rods, and depositing S4 metal nanoparticles in the metal oxide layer.

Advantages of the present invention comprise:
a SERS surface with a large analysis surface area;
a SERS surface with increased sensitivity to ultra low concentrations of molecules in gases or liquids;
a SERS surface with nanoparticles with controlled size and distribution and
a SERS surface made out of a self-cleaning metal oxide. This makes the handling of the surface much easier, since the sample preparation can be performed under a UV lamp. Other SERS surfaces have to be used directly after breaking the sealed package, this is not necessary for the present invention.

### ABBREVIATIONS

ALD Atomic Layer Deposition

CVD Chemical Vapor Deposition

MO-CVD Metal Organic CVD

PVD Physical Vapor Deposition

MBE Molecular Beam Epitaxy

SERS Surface Enhanced Raman Spectroscopy

SEM Scanning Electron Microscopy

UV Ultra Violet

### BRIEF DESCRIPTION OF THE DRAWINGS

The invention, together with further objects and advantages thereof, may best be understood by referring to the following description taken together with the accompanying drawings, in which:

FIG. 1 is a schematic flow chart of an embodiment of the method according to the present invention;

FIG. 2 is a schematic image of a nanostructured template e.g. porous anodic alumina;

FIG. 3a-d is a schematic illustration of atomic layer deposition (ALD);

FIG. 4a-d show a schematic description of an embodiment of the method according to the invention.

FIG. 5a-d show a schematic description of an alternative embodiment of the method of the invention.

FIG. 6 is a SEM image of a surface structure according to the present invention;

FIG. 7a-d is a schematic illustration of a further embodiment of the present invention.

### DETAILED DESCRIPTION

The present invention will be described in the context of Surface Enhanced Raman Spectroscopy (SERS) and detection of minute amounts of substances using SERS. However, the structures and methods described below can additionally be utilized for catalysis, batteries, fuel-cells, quantum wells and magnetic structures etc.

One of the aims of the present invention is to provide a cheap, self-cleaning sensor surface with nano sized structures to optimize e.g. the Raman scattering in order to provide maximum signal amplification.

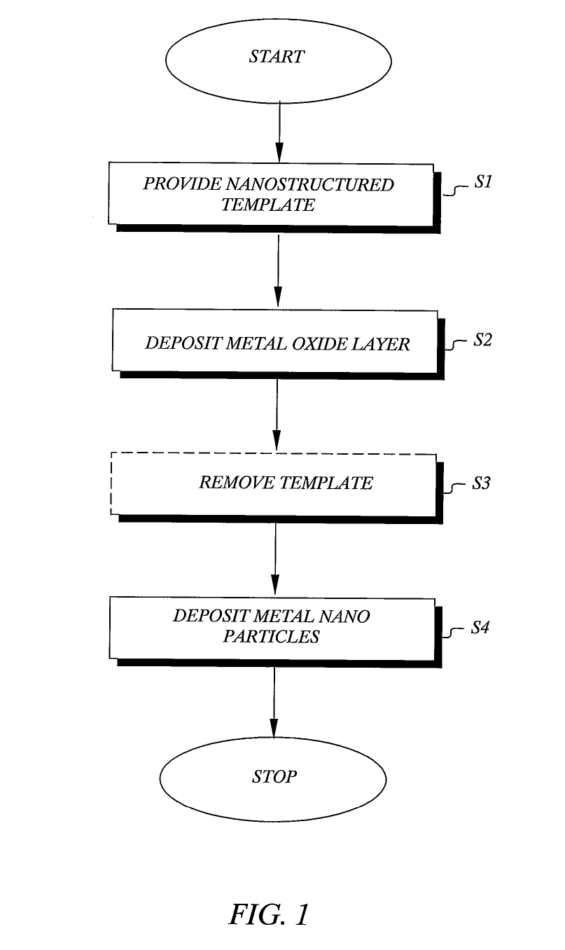

With reference to FIG. 1, the present invention comprises providing S1 a nanostructured template e.g. porous alumina oxide template or nano-rod array, and depositing S2 at least one layer of a metal oxide based material, on the template. Subsequently, nanoparticles are deposited S4 on or in the vicinity of the metal oxide layer. The template is preferably made from a metal oxide material, and the nano particles are preferably metal particles. the nanostructured template is optionally removed S3 e.g. by etching.

The embodiments of the present invention will mainly be described using a nanostructured template in the form of a porous substrate. However, it is equally applicable to utilize another nanostructured template, such as an arrangement of nano-rods or whiskers on a substrate surface.

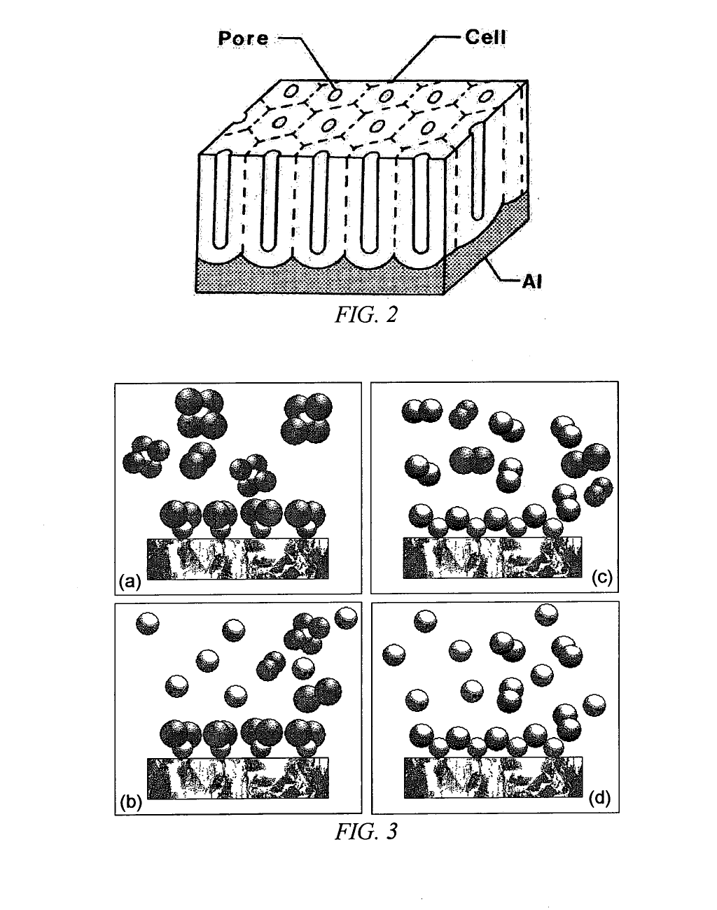

According to a specific embodiment the nanostructured template comprises a so called porous anodic alumina membrane, see FIG. 2. According to known techniques, this membrane is typically fabricated by an electrochemical process where an aluminium substrate is connected as anode and an inert material, like platinum, gold or even lead, is connected as cathode. As electrolyte e.g. phosphoric acid, sulphuric acid, oxalic acid or chromic acid can be used. By applying a constant voltage of ˜25-200 V the aluminium oxidizes and a porous oxide is formed. The pore size of the oxide is dependent upon the anodisation voltage and the oxide thickness is dependent on the anodisation time, pH of the electrolyte, and temperature.

The produced anodic alumina membranes are subsequently, according to a specific embodiment of the present invention, used as the nano-structured substrate or template for e.g. atomic layer deposition (ALD). ALD (see FIG. 3) is a known gas phase chemical deposition technique in which reactant gases (represented by the molecules above and attached to the substrate) are introduced to a substrate in pulses. The reactant pulses are separated by purging pulses of an inert gas, e. g. nitrogen or argon.

According to an embodiment of the present invention, a metal containing precursor is initially evaporated and flowed over a substrate (FIG. 3a.). A purging pulse removes excess of precursors, except one monolayer which is adsorbed to the substrate surface (FIG. 3b.). A third pulse (FIG. 3c.), containing an oxygen source (e. g. O₂, H₂O or H₂O₂) is introduced and reacts with the first precursor to form a monolayer of metal oxide. In the last pulse (FIG. 3d.), excess of gases as well as by-product is purged with the same inert gas as in the second pulse. This scheme can be repeated a desired number of times in order to tailor the thickness of the metal oxide layer.

As previously stated, the template e.g. anodic alumina substrate is subsequently removed by etching in a diluted phosphoric acid solution or a sodium hydroxide solution, or equivalent solution. Consequently, an ordered array of metal oxide nanotubes remain after etching.

To enable amplification of the Raman signal in SERS it is subsequently necessary to provide metal nanoparticles on the walls of the nanotubes.

For a satisfactory material used as enhancing surface in SERS analysis it is necessary to have a surface containing silver, gold, copper or even palladium, which is textured in the nano dimension. In order to strongly enhance the Raman signal it is also important that the surface is large. By depositing nanoparticles, which densely cover the metal oxide nanotubes, which have a large microscopic surface, a very large metal nanoparticle surface is obtained. In order to optimise the yield in the SERS analysis it is necessary to choose a light source of proper wavelength, which in turn is dependent on the nano particles size. The analytical yield is also dependent on the adsorption of the substance to be analysed, which means that the surface, here the metal nanoparticles, has to be optimised with respect to size, geometry and composition. Another important factor for SERS analysis is the importance of having a non-contaminated surface; therefore it is necessary that the analysing surface is self-cleaning or possible to clean by either heating or irradiation with light. Titanium oxide (especially the anatase phase) surfaces are known to self-clean photo-catalytically from organic contaminants under irradiation of ultra-violet (UV) light.

The nanotubular structure described above is a material with tube diameters which can be tailored from 5 nm to about 400 nm. The tube lengths can be as long as 100 μm. An advantage by providing a nanostructured metal surface on the tube walls of a nanotubular material such as the above described metal oxide nanotubes is that instead of receiving information from a surface layer, information from a 3-D volume will be detected. This means that the sensitivity will increase drastically, i.e., instead of receiving information from a nanostructured surface layer, information from thousands of equivalent layer will be achieved, increasing the sensitivity considerably.

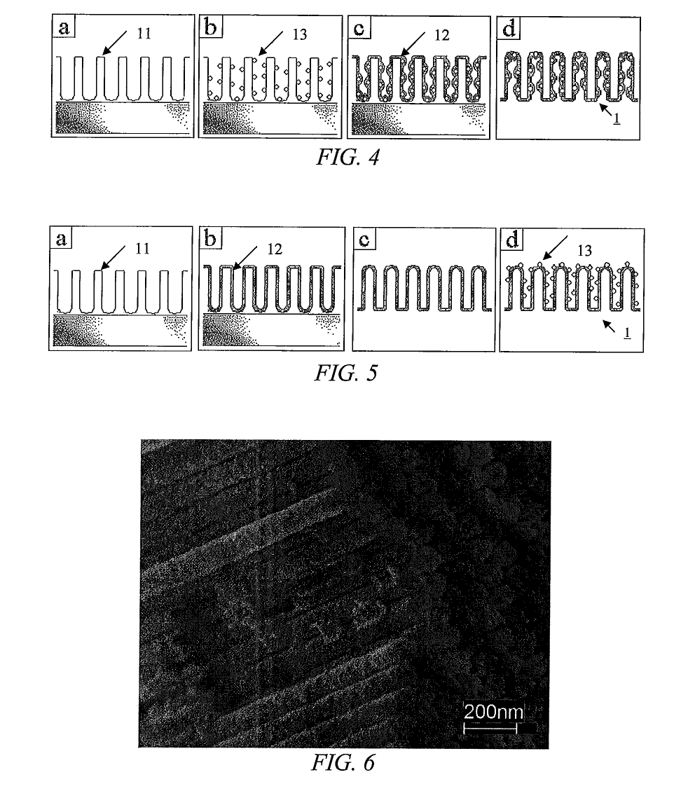

According to a specific embodiment, the invention comprises a template based method of manufacturing a 3-D structure comprising an arrangement of metal oxide nanotubes with deposited nanoparticles on the tube walls. The metal nanoparticles can either be fabricated on the pore walls of the anodic alumina substrate prior to metal oxide deposition (FIG. 4a-d), or be deposited directly on the fabricated metal oxide nanotubes after etching away the anodic alumina template (FIG. 5.a-d).

The thus manufactured nano tubular structured surface with nano particles attached to it is shown in the SEM image of FIG. 6.

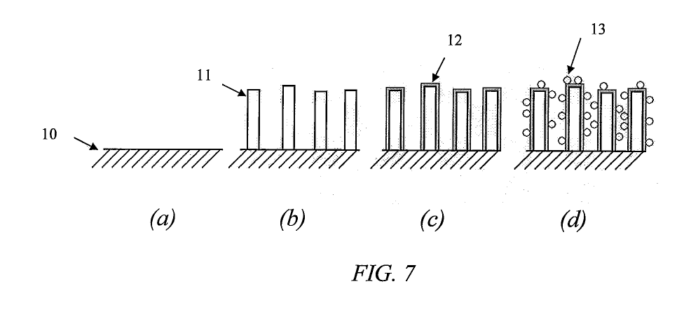

With reference to FIG. 7a-d, according to a further embodiment, the invention comprises a template based method of manufacturing a 3-D structure comprising an arrangement of metal oxide nanorods with deposited nanoparticles on the rods.

Consequently, a nanostructured template in the form of an arrangement of whiskers or nano-rods 11 on a planar substrate 10 is provided. The substrate 11 is preferably clean and flat and comprises metal or ceramic. Subsequently, whiskers or nano-rods are grown either by wet chemical methods or CVD, ALD, MO-CVD or laser-CVD. The whiskers can comprise any metal oxide, for example zinc oxide, titanium oxide or tin oxide.

If the whiskers are fabricated by means of wet chemical methods the surfaces might be contaminated. Since SERS is very sensitive to contaminants it is then important to have an extremely clean surface. This can be achieved by depositing at least one metal oxide layer 13, according to the invention, on the whiskers. The layer can be deposited by ALD, CVD, MO-CVD or laser-CVD (or any equivalent methods). Another reason for applying the oxide layer might be the self cleaning photocatalytical properties of for example titanium oxide. Finally, the metal nanoparticles are added by any of the methods provided below.

The metal nanoparticles can be deposited by means of ALD or CVD, using a method similar to the one described earlier. However, here the first precursor gas must contain silver ions and the second precursor gas must be a reducing agent in order to reduce the first precursor to metallic silver.

The metal nanoparticles can also be deposited by a solution based technique. First the nano-tube sample is exposed to a solution containing Sn²⁺ ions. The sample is then cleaned in deionized water to remove all tin ions except one layer adsorbed to the surface of the nanotubes. After cleaning the sample is exposed to a solution containing Ag⁺ ions. The silver ions (Ag⁺) are reduced to metallic silver (Ag) while the tin ions are further oxidized (Sn²⁺→Sn⁴⁺). The above mentioned synthesis cycling scheme is repeated an arbitrarily number of times until the desired size of the silver particles is reached.

According to a specific embodiment the deposition solutions are a silver containing solution e.g. silver nitrate (AgNO₃) and a Sn²⁺ containing solution e.g. SnCl₂ to provide silver nano particles The concentrations of the tin and silver solutions can be varied within the interval 1×10⁻⁶ to 15 M depending on the desired geometry and distribution of the particles.

According to another specific embodiment, the deposition solution can be varied between the deposition cycles to provide a multilayered structure. For instance, in order to enable depositing gold nanoparticles on the pore walls of anodic alumina using the method according to the invention. Palladium can be deposited by utilizing a deposition solution containing a palladium hexaamin, Pd(NH₃)₆²⁺ complex. In that case the resulting nanoparticles will comprise an inner silver or palladium core surrounded by at least one atomic layer of gold. A suitable gold containing solution is Auric acid or HAuCl₄ with a concentration in the interval 1×10⁻⁶ to 5 M.

Multilayer particles comprising a plurality of elements can be fabricated by exposing the metal oxide nanotubes to a plurality of different deposition solution during the deposition cycles.

By first depositing silver nanoparticles and later depositing gold on top of the already existing silver nanoparticles, core- and shell nanoparticles can be produced. Silver can be deposited again and form a third layer. This can be repeated for several times and other metal salts or compounds can be used as deposition solution; e.g. platinum, copper, nickel, cobalt, rhodium, iridium, and palladium.

Yet another embodiment of the present invention comprises annealing the deposited multilayer nanoparticles after the deposition cycles are performed. This enables alloyed nanoparticles to be deposited on the pore walls of the anodic alumina membrane.

Depending on how long time the structure is annealed and if the structure is annealed after all deposition cycles are completed or between deposition cycles, the alloyed nanoparticles can have a concentration gradient from the centre to the surface or concentration gradients between the internal layers.

An embodiment of a SERS surface according to the invention is shown in the SEM photograph in FIG. 6, where the structure comprises an array of metal oxide nanotubes attached to a stabile surface. The metal oxide nanotubes are preferably fabricated by ALD using porous anodic alumina as template. The porous anodic alumina can be removed by chemical etching in phosphoric acid.

It is understood that the number of layers and the constituents of each layer in the nanoparticles composition can be varied without departing from the invention.

In conclusion, the invention basically comprises an arrangement of metal oxide nanotubes or rods, which has been subjected to silver, gold or palladium nanoparticle deposition on or in the tube walls. The deposition was made either by ALD or by a deposition technique based on solutions of the metal compounds. The sizes as well as the composition of the deposited particles on the tube walls can be tailored by variation of the deposition parameters.

One possible application for the invention comprises the use of the arrangement with metal oxide nanotubes or nanorods with deposited nanoparticles as a SERS surface for use in Raman spectrometers to enhance the Raman signal. This enables detection of very low concentrations of gases and dissolute substances. However, other possible fields of applications for the structure of the invention comprise catalysis, batteries, fuel-cells, quantum wells and magnetic structures.

Many studies have been done to date for the purpose of creating a good SERS surface. Most of the studies are based on lithographically patterned gold or silver surfaces, which give good control of the surface topography, but lack the highly enlarged surface, which is required for analysing very low concentrations. Another advantage with the present invention is the self-cleaning properties which some metal oxides (e.g. TiO₂) have. That advantage makes SERS surfaces described in the present invention easier to handle, lowering the contamination risk, compared to, e.g., lithographically fabricated SERS surfaces.

According to a specific example of the invention, an array of metal oxide nanotubes are produced by ALD, using a metal containing precursor (e.g. TiI₄) and an oxygen source (e.g. water) in porous anodic alumina templates which are later removed by etching. Silver particles are deposited on the tube walls on an array of metal oxide nanotubes using a silver nitrate solution (concentration between 1×10⁻⁶ and 15 M) and a tin chloride solution (concentration between 1×10⁻⁶ and 15 M) which is applied sequentially to the SERS surface with cleaning steps using water in between. The deposition procedure can be repeated several times in order to tailor the size and size distribution of the formed nanoparticles, since the particles increase in size with every deposition cycle.

The particle size can be monitored by: controlling the concentrations of silver nitrate and tin chloride in the deposition solutions, and by varying the number of deposition cycles.

According to another specific example of the invention, an arrangement of metal oxide nanotubes are produced by ALD, using a metal containing precursor (e.g. TiI₄) and an oxygen source (e.g. water) in porous anodic alumina templates which are later removed by etching. Silver particles are deposited on the tube walls on an array of metal oxide nanotubes using atomic layer deposition (ALD) and a silver containing precursor. The ALD cycle scheme can be repeated several times in order to tailor the size and size distribution of the formed nanoparticles, since the particles increase in size with every deposition cycle. The deposition temperature does also influence the particle size and distribution.

The size of the deposited nanoparticles can be tailored by means of controlling the deposition temperature of the ALD process, and/or varying the number of ALD cycles.

Depending on the area of application the structure of the array of metal oxide nanotubes or rods and the nanoparticles can be varied as follows:
1. The nanotube length can be varied between 0.1-100 μm.
2. The distances between the nanotubes can be varied between 20-500 nm
3. The tube diameters can be varied between 5-400 nm
4. The silver nanoparticles on the tube walls of the metal oxide nanotubes can have diameters ranging between 0.5 nm-100 nm.
5. The coverage of the silver nanoparticles on the tube walls of the array of nanotubes can be varied between direct contacts between particles to 1 particle per μm².
6. The gold nanoparticles on the pore tube walls of the array of nanotubes can have diameters ranging between 0.5 nm-100 nm.
7. The coverage of the gold nanoparticles on the tube walls of the array of nanotubes can be varied between direct contacts between particles to 1 particle per μm².
8. The multilayer nanoparticles on the tube walls of the array of nanotubes can have diameters ranging between 0.5 nm-100 nm.
9. The coverage of the multilayer nanoparticles on the tube walls of the array of nanotubes can be varied between direct contacts between particles to 1 particle per μm².
10. The alloy nanoparticles on the pore tube walls of the array of nanotubes can have diameters ranging between 0.5 nm-50 nm.
11. The coverage of the alloy nanoparticles on the tube walls of the array of nanotubes can be varied between direct contacts between particles to 1 particle per μm².

Although the present invention has been described in the context of ALD, the metal oxide nano-tubular structure can equally well be fabricated by whisker techniques, by MBE, by CVD, modifications of the CVD technique and PVD with modifications. It can also be prepared by using sol-gel methods and other wet chemical techniques. The metal nanoparticles can be deposited on the metal oxide surfaces by wet chemical techniques, by CVD and by PVD. The metal nanoparticles can also be fabricated outside the metal oxide nanostructure and then be introduced to the structure and adsorbed to the surfaces. Techniques for nanoparticles formation includes, wet chemical methods, laser-CVD techniques and laser ablation.

In conclusion, the present invention provides a synthesis route to fabricate metal oxide nanotubes or nanorods and to grow nanoparticles on or in the tube or rod walls of metal oxide nanotubes. By applying the proper fabrication parameters and deposition conditions the nanotube dimensions and order and the particle size as well as the particles density (number of particles per area unit) and particle composition can be tailored.

Advantages of the method of manufacture and the structures according to the invention include:
a SERS surface with a large analysis surface area;
a SERS surface with increased sensitivity to ultra low concentrations of molecules in gases or liquids;
a SERS surface with nanostructures with controlled size and distribution.
a SERS surface which can be self-cleaned by exposure to UV irradiation.

It will be understood by those skilled in the art that various modifications and changes may be made to the present invention without departure from the scope thereof, which is defined by the appended claims.

1.-20. (canceled)

21. A method of manufacturing a surface structure for improved Surface Enhanced Raman Spectroscopy (SERS), comprising the steps of:
providing a nanostructured template;
depositing at least one layer of a metal oxide on said template; and
depositing nanoparticles;
whereby a nanostructured arrangement comprising nanotubes or nanorods with deposited nanoparticles in or on said at least one layer is formed.

22. The method according to claim 21, wherein said nanostructured template comprises a porous template.

23. The method according to claim 22, further comprising the step of removing the nanostructured template to provide a surface structure comprising said arrangement of metal oxide nanotubes or nanorods with the nanoparticles associated with the nanotube or nanorod walls.

24. The method according to claim 21, wherein said nanostructured template comprises an arrangement of nanorods or whiskers.

25. The method according to claim 21, wherein the step of depositing the metal oxide layer comprises atomic layer deposition.

26. The method according to claim 21, wherein the step of depositing the metal oxide layer comprises one of: whisker techniques, Molecular Beam Epitaxy (MBE), Chemical Vapor Deposition (CVD), Physical Vapor Deposition (PVD), sol-gel, or wet chemical techniques.

27. The method according to claim 21, wherein the step of depositing the nanoparticles comprises atomic layer deposition.

28. The method according to claim 21, wherein the step of depositing the nanoparticles comprises one of: wet chemical techniques, Chemical Vapor Deposition (CVD), or Physical Vapor Deposition (PVD).

29. The method according to claim 23, wherein the step of depositing the nanoparticles comprises the sub-steps of:
providing nanoparticles;
introducing the nanoparticles to the nanotubes; and
adsorbing the nanoparticles to the outer walls of said nanotubes.

30. The method according to claim 29, wherein said nanoparticles are provided by means of any wet chemical process and/or laser-Chemical Vapor Deposition (CVD), and/or laser ablation.

31. The method according to claim 22, wherein said nanoparticles are deposited on the template prior to depositing the metal oxide layer.

32. The method according to claim 21, wherein said nanoparticles are deposited on said metal oxide layer.

33. The method according to claim 23, further comprising the step of removing said porous template by means of etching.

34. The method according to claim 22, wherein said porous template comprises a porous alumina substrate.

35. A sensor surface structure comprising a nanostructured arrangement, wherein said arrangement comprises:
at least a deposited layer of a metal oxide; and
deposited nanoparticles in or on said deposited layer.

36. The sensor surface structure according to claim 35, wherein said arrangement comprises an array of nanotubes.

37. The sensor surface structure according to claim 35, wherein said arrangement comprises an array of nanorods.

38. The sensor surface structure according to claim 35, wherein said metal oxide is selected from the group consisting of titanium oxide, zinc oxide, tin oxide, niobium oxide, hafnium oxide, tungsten oxide, copper oxide, and aluminum oxide.

39. The structure according to claim 35, wherein said nanoparticles comprise metal nanoparticles.

40. The structure according to claim 39, wherein said metal is at least one of silver, gold, copper, iridium, rhodium, or palladium.

41. A method of manufacturing a surface structure for improved Surface Enhanced Raman Spectroscopy (SERS), comprising the steps of:
providing a nanostructured template;
depositing at least one layer of a metal oxide on said template; and
depositing nanoparticles on said at least one layer.

42. The method according to claim 41, wherein said nanostructured template comprises a porous template.

43. The method according to claim 42, further comprising the step of removing the nanostructured template to provide a surface structure comprising said arrangement of metal oxide nanotubes with the nanoparticles associated with the nanotube walls.

44. The method according to claim 41, wherein said nanostructured template comprises an arrangement of nanorods or whiskers.

45. A method of manufacturing a surface structure for improved SERS, comprising the steps of:
providing a nanostructured template comprising a porous template;
depositing nanoparticles on said template; and
depositing at least one layer of a metal oxide on said template.

46. The method according to claim 45, further comprising the step of removing the nanostructured template to provide a surface structure comprising said arrangement of metal oxide nanotubes with the nanoparticles associated with the nanotube walls.
